(19) United States
(12) Patent Application Publication
(10) Pub. No.: US 2025/0189444 A1
(43) Pub. Date: Jun. 12, 2025

(54) RADIATION EMITTER AND MEASUREMENT SYSTEM

(71) Applicant: Industrial Technology Research Institute, Hsinchu (TW)

(72) Inventors: Karthickraj Muthuramalingam, Hsinchu City (TW); Chen-Peng Hsu, Hsinchu City (TW)

(73) Assignee: Industrial Technology Research Institute, Hsinchu (TW)

(21) Appl. No.: 18/935,621

(22) Filed: Nov. 3, 2024

Related U.S. Application Data
(60) Provisional application No. 63/607,563, filed on Dec. 8, 2023.

(51) Int. Cl. G01N 21/3581; G01N 21/3563; G01N 21/95

(52) U.S. Cl. CPC G01N 21/3581; G01N 21/3563; G01N 21/9501; G01N 2201/06113; G01N 2201/0636

(57) ABSTRACT

A radiation emitter and a measurement system are provided. The radiation emitter includes: a first light source, emitting a first light beam transmitting along a first light path; a polarizer, disposed on the first light path of the first light beam; and at least one mirror, disposed on the first light path of the first light beam, wherein the first light beam is reflected by a first mirror of the at least one mirror to leave the radiation emitter.

### CROSS-REFERENCE TO RELATED APPLICATION

This application claims the priority benefit of U.S. provisional application Ser. No. 63/607,563, filed on Dec. 8, 2023. The entirety of the above-mentioned patent application is hereby incorporated by reference herein and made a part of this specification.

### BACKGROUND

### Technical Field

The present invention relates generally to a radiation emitter and a measurement system.

### Background

THz-radiation is widely used in non-contact measurements such as semiconductor wafer inspections. In traditional THz detection systems, the THz radiation emitted by THz light source, such as the photo conductive antennas, is hard to align with the optical axis, thus the THz radiation cannot be focused properly on the sample and reduces the measurement quality.

### SUMMARY

According to one embodiment of this disclosure, a radiation emitter is provided. The radiation emitter includes: a first light source, emitting a first light beam transmitting along a first light path; a polarizer, disposed on the first light path of the first light beam; and at least one mirror, disposed on the first light path of the first light beam, wherein the first light beam is reflected by a first mirror of the at least one mirror to leave the radiation emitter.

According to another embodiment of this disclosure, a measurement system is provided. The measurement system includes: a laser source, emitting a laser beam; a beam splitter, split the laser beam into a first portion of the laser beam and a second portion of the laser beam; a sample stage, configured to hold a sample; a radiation emitter, receiving a first portion of the laser beam, comprising: a first light source, emitting a first light beam, according to the first portion of the laser beam, transmitting along a first light path to the sample to generate a first reflected light beam; a polarizer, disposed on the first light path of the first light beam; and at least one mirror, disposed on the first light path of the first light beam, wherein the first light beam is reflected by a first mirror of the at least one mirror to leave the radiation emitter to the sample; a radiation detector, receiving a second portion of the laser beam, comprising: at least one receiver, receiving a portion of a first reflected light beam; and a lock-in amplifier, connecting to the radiation detector and receiving detected signals from the radiation detector.

### BRIEF DESCRIPTION OF THE DRAWINGS

FIG. 1 is a schematic diagram of a measurement system according to an embodiment of the present disclosure.

FIG. 2 is a schematic diagram of a radiation emitter of a measurement system according to an embodiment of the present disclosure.

FIG. 3 is a schematic diagram of a radiation emitter of a measurement system according to an embodiment of the present disclosure.

FIG. 4 is a schematic diagram of a radiation emitter of a measurement system according to an embodiment of the present disclosure.

FIG. 5 is a schematic diagram of a radiation emitter of a measurement system according to an embodiment of the present disclosure.

FIG. 6 is a schematic diagram of a radiation emitter and a radiation detector of a measurement system according to an embodiment of the present disclosure.

FIGS. 7A and 7B are examples of a measurement result of the measurement system according to an embodiment of the present disclosure.

### DESCRIPTION OF THE EMBODIMENTS

Following embodiments are provided in collaboration with the accompanying drawings for detailed description, but the provided embodiments are not used to limit a scope of the disclosure. In addition, component sizes in the drawings are drawn for convenience of explanation, and do not represent the actual component sizes. Moreover, although “first”, “second”, etc. are used in the text to describe different components and/or film layers, these components and/or film layers should not be limited to these terms. Rather, these terms are only used to distinguish one component or film layer from another component or film layer. Therefore, a first component or film layer discussed below may be referred to as a second element or film layer without departing from the teachings of the embodiments. To facilitate understanding, similar components are described with the same symbols in the following description.

In the description of the embodiments of the disclosure, different examples may use repeated reference symbols and/or words. These repeated symbols or words are for the purpose of simplification and clarity, and are not used to limit a relationship between the various embodiments and/or the appearance structure. Furthermore, if the following disclosure of the specification describes that a first feature is formed on or above a second feature, it means that it includes an embodiment in which the formed first feature and the second feature are in direct contact, and also includes an embodiment in which an additional feature is formed between the first feature and the second feature, so that the first feature and the second feature may not be in direct contact. To facilitate understanding, similar components are described with the same symbols in the following description.

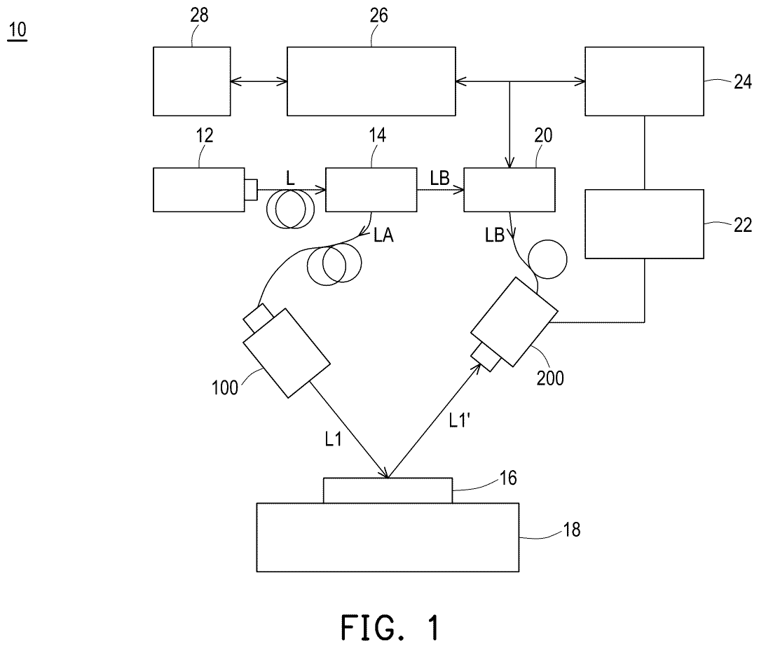

FIG. 1 is a schematic diagram of a measurement system according to an embodiment of the present disclosure.

Please refer to FIG. 1. The measurement system 10 includes a laser source 12, a beam splitter 14, a sample stage 18, a radiation emitter 100, a radiation detector 200, and a lock-in amplifier 24.

A laser source 12 emits a laser beam L. The laser beam L transmits to the beam splitter 14 through an optical fiber. In some embodiments, the laser source 12 is a femto-second laser source, and the laser beam L is a femto-second laser.

The beam splitter 14 splits the laser beam L into a first portion of the laser beam LA and a second portion of the laser beam LB. The first portion of the laser beam LA is transmitted to the radiation emitter 100 by an optical fiber. The second portion of the laser beam LB is transmitted to the radiation detector 200 through a delay line 20 and an optical fiber.

In some embodiments, the ratio of the intensities of the first portion of the laser beam LA and the second portion of the laser beam LB is between 30:70 to 70:30, preferably 50:50.

The radiation emitter 100 receives a first portion of the laser beam LA and emits a first light beam L1 to a sample 16. The detailed structure of the radiation emitter 100 will be discussed in later paragraphs.

The sample 16 is held by a sample stage 18. In some embodiments, the sample 16 is a semiconductor wafer. In some embodiments, the sample 16 may be a wafer with a diameter between 4 to 8 inches. However, larger or smaller wafers may also be possible, which is not limited thereto.

In some embodiments, the sample stage 18 is an XY table, which moves the sample 16 along X and Y directions. In some embodiments, the sample stage 18 rotates sample 16. By moving and rotating the sample 16, the sample 16 may be scanned thoroughly by the first light beam L1.

The first light beam L1 is directed to the sample 16, and is reflected by the sample 16 as the first reflected light beam L1′. The first reflected light beam L1's thus carries the information of the sample 16. A portion of the first reflected light beam L1′ is received by the radiation detector 200.

The radiation detector 200 receives a portion of the first reflected light beam L1′ from the sample. The radiation detector 200 also receives a second portion of the laser beam LB from the beam splitter 14. The radiation detector 200 sends the detected signal according to the first reflected light beam L1′ and the second portion of the laser beam LB to the pre-amplifier 22 to amplify the detected signal.

The lock-in amplifier 24 is connected to the radiation detector 200 and receiving detected signals from the radiation detector 200. The lock-in amplifier 24 compares the detected signal from the radiation detector 200 and the reference signal to extract the signal corresponding to the properties of the sample 16.

The signal extracted by the lock-in amplifier 24 is sent to the data acquisition and control unit 26. The signal is then processed and sent to a computer 28 for further analysis.

Below is the detailed explanation on the radiation emitter 100 and the radiation detector 200.

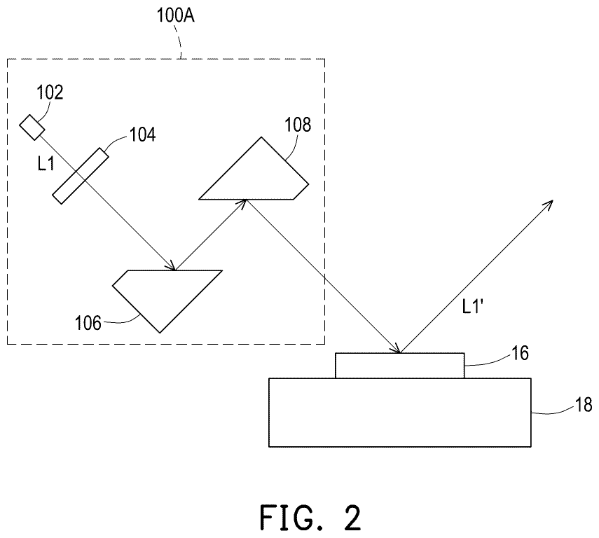

FIG. 2 is a schematic diagram of a radiation emitter of a measurement system according to an embodiment of the present disclosure.

A radiation emitter 100A is an embodiment of the radiation emitter 100 shown in FIG. 1. The radiation emitter 100A includes a first light source 102, a polarizer 104, and at least one mirror (mirrors 106 and 108).

The first light source 102 emits a first light beam L1 transmitting along a first light path to the sample 16 to generate a first reflected light beam L1′. The first light beam L1 is a THz radiation. In some embodiments, the frequency range of the first light beam L1 is between 0.1 to few hundred THz. In some embodiments, the first light source 102 is a photoconductive antenna, or an array of photoconductive antennas, which is excited by the first portion of the laser beam LA as shown in FIG. 1.

The polarizer 104 is disposed on the first light path of the first light beam L1. In some embodiments, the polarizer 104 is a linear polarizer. The polarizer 104 may be a S-type polarizer or a P-type polarizer, depending on the desired polarization direction of the first light beam L1. Here, the S-type polarization refers to the electric field of the light beam is perpendicular to the plane of incidence. The P-type polarization refers to the electric field of the light beam is parallel to the plane of incidence.

In some embodiments, the polarizer 104 may be arranged in other desirable positions along the first light path. In some embodiments, the polarizer 104 may be disposed between the mirror 108 and the sample 16.

At least one mirror is disposed on the first light path of the first light beam L1 to leave the radiation emitter 100A and to the sample 16. In this embodiment, the number of mirrors is two. However, the number of mirrors and the location of disposing the mirrors depends on the desired properties and the design of the radiation emitter 100A, which is not limited to.

In some embodiments, the mirrors 106 and 108 are off-axis parabolic (OAP) mirrors. The off-axis parabolic mirrors have the ability to focus collimated light without introducing spherical aberration. The first light beam L1 that is incident to the OAP mirrors 106 and 108 is focused. The first light beam L1 is then reflected by the mirror 112 to leave the radiation emitter 100A to the sample 16.

When a typical THz radiation source, such as a photoconductive antenna, emits a typical THz radiation, it is often that the emitted photoconductive antenna is off the optical axis of the THz radiation source. Thus, the emitted THz radiation will encounter a serious reflection plane mismatch issue when the THz radiation is reflected by a mirror.

However, with the arrangement shown in FIG. 2, the off-axis arrangement of the mirrors 106 and 108 allows the adjustment of optical axis of the first light beam L1, such that the unexpected optics axis misalignment from the first light source 102 may be compensated. The circular spot formed on the sample 16 due to the first light beam L1 may also be adjust able.

Furthermore, in the arrangement shown in FIG. 2, the radiation emitter 100A does not have a lens in the optical setup. The first light beam L1 is transmitted between the OAP mirrors by reflection. Thus, there is less aberration and less loss of the first light beam L1 due to no material absorption if the first light beam L1 has to transmits through the lens-like optical components.

In order to provide better alignment of the THz radiation, another visible light source may be provided to help the alignment.

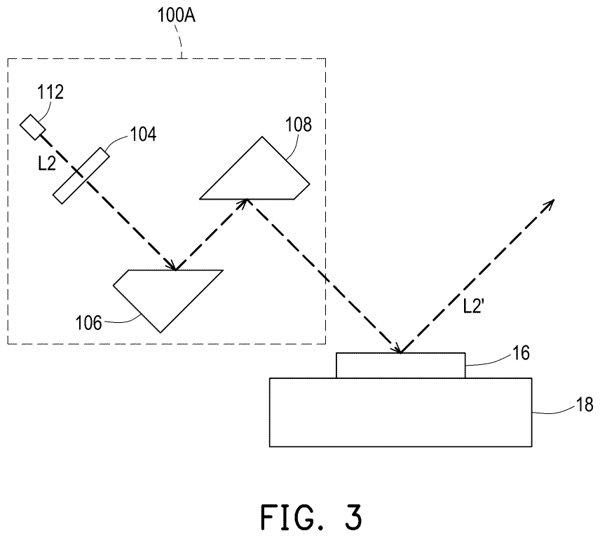

FIG. 3 is a schematic diagram of a radiation emitter of a measurement system according to an embodiment of the present disclosure.

The arrangement of FIG. 3 is similar to the arrangement of FIG. 2. The difference is that the first light source 102 is replaced with a second light source 112.

The second light source 112 emits a second light beam L2 transmitting along a second light path. In some embodiments, the second light beam L2 is a visible light. The second light source 112 is a visible light source.

As shown in FIG. 3, the mirrors 106 and 108 are not only reflective to the THz first light beam L1, but also reflective to the visible light L2.

As shown in FIG. 3, the second light path of the second light beam L2 is identical to the first light beam L1. Thus, the second light beam L2 may be used to calibrate the first light path of the invisible THz first light beam L1. Specifically, when the second light beam L2 is shown on the sample, a light spot due to the second light beam L2 may be formed. By comparing the location of the light spot produced due to the first light beam L1, one can tell whether the optical axis mismatch of the first light beam L1 is compensated or not. When the optical axis mismatch of the first light beam L1 is fully compensated, the first light spot of the first light beam L1 formed on a sample 16 and a second light spot of the second light beam L2 formed on the sample 16 are overlapping.

In the arrangement of FIG. 2 and FIG. 3, in order to calibrate the optical axis of the first light beam L1 (FIG. 2), the first light source 102 has to be replaced by the second light source 112. Thus, this is also referred as an off-line alignment of the first light beam L1.

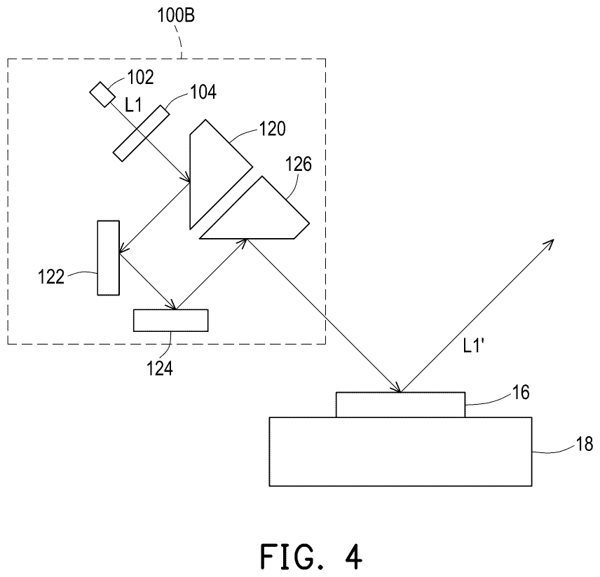

FIG. 4 is a schematic diagram of a radiation emitter of a measurement system according to an embodiment of the present disclosure.

The radiation emitter 100B is an embodiment of the radiation emitter 100 shown in FIG. 1, and is similar to the radiation emitter 100A shown in FIG. 2. The difference is that, as shown in FIG. 4, the first light path of the first light beam L1 now are directed by four mirrors 120, 122, 124, and 126 to the sample 16. To be more specific, the mirrors 120 and 126 are OAE mirrors, and the mirrors 122 and 124 are plane mirrors.

With more reflective mirrors along the first light path of the THz first light beam L1, it is easier to compensate the optical axis mismatch of the first light beam L1.

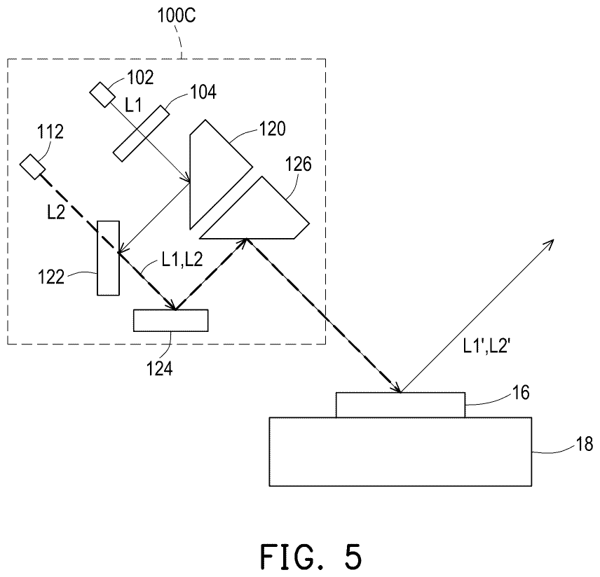

FIG. 5 is a schematic diagram of a radiation emitter of a measurement system according to an embodiment of the present disclosure.

The radiation emitter 100C is an embodiment of the radiation emitter 100 shown in FIG. 1, and is similar to the radiation emitter 100B shown in FIG. 4. The difference is that, as shown in FIG. 5, the second light source 112 is disposed in a position different from the first light source 102. The second light beam L2 emitted by the second light source 112 transmits through the mirror 122, be reflected by the mirrors 124 and 126, to the sample 16.

As shown in FIG. 5, the mirror 122 reflects first light beam L1, which is the THz radiation, and transmits the second light beam L2, which is a visible light. Starting from the mirror 122, the optical paths of the first light beam L1 and the second light beam L2 overlaps with each other. In other words, the optical paths of the first light beam L1 and the second light beam L2 partially overlaps with each other.

In the radiation emitter 100C, the first light source 102 and the second light source 112 are present at the same time, and can emit the first light beam L1 and the second light beam L2 simultaneously. Thus, the second light beam L2 can be used to calibrate the mismatch of the optical axis of the first light beam L1 in real time, which is different from the radiation emitter 100A shown in FIGS. 2 and 3. Thus, the radiation emitter 100C can calibrate the mismatch of the optical axis of the first light beam L1 more efficiently.

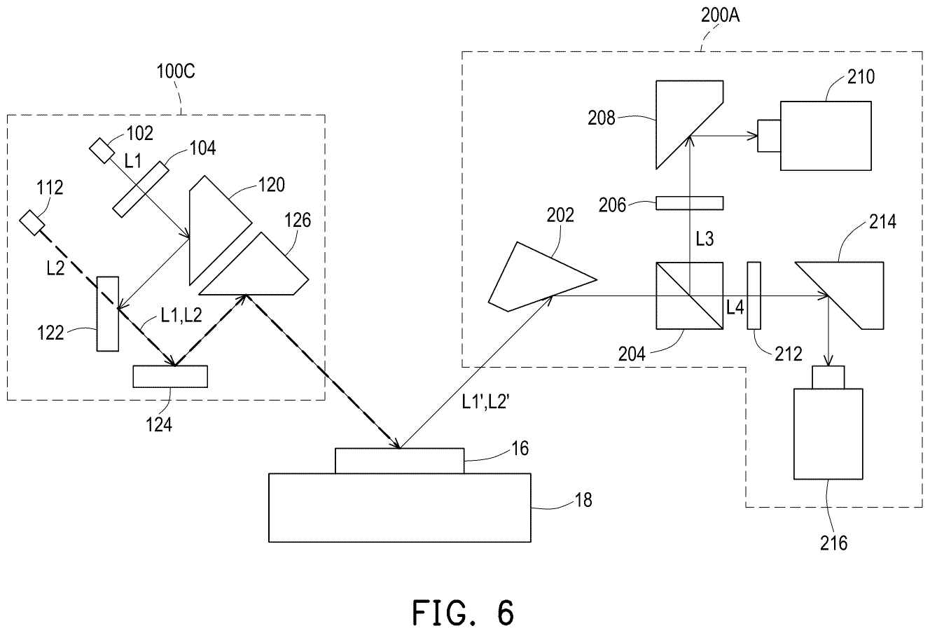

FIG. 6 is a schematic diagram of a radiation emitter and a radiation detector of a measurement system according to an embodiment of the present disclosure.

As shown in FIG. 6, the radiation emitter 100C as shown in FIG. 5 is used in this embodiment. However, the radiation emitter 100A as shown in FIGS. 2 and 3, or the radiation emitter 100B as shown in FIG. 4 may be used here as well, which is not limited thereto.

The radiation detector 200A is an embodiment of the radiation detector 200 shown in FIG. 1.

The radiation detector 200A includes at least one receiver to receive a portion of a first reflected light beam L1′ from the sample 16. As shown in FIG. 6, the radiation detector 200A includes a first receiver 210 and a second receiver 216, which will be discussed later.

As shown in FIG. 6, the radiation detector 200A further includes a beam splitter 204, disposed on a third light path of the first reflected light beam L1′. The first reflected light beam L1′ enters the beam splitter 204 along the third light path which includes being reflected by the mirror 202. The beam splitter 204 splits the first reflected light beam L1′ to a first portion of the first reflected light beam L3 and a second portion of the first reflected light beam LA.

The radiation detector 200A further includes a first polarizer 206 and a second polarizer 212. The first polarizer 206 is disposed between the beam splitter 204 and the first receiver 210. The second polarizer 212 is disposed between the beam splitter 204 and the second receiver 216.

The first portion of the first reflected light beam L3 transmits through the first polarizer 206 to the first receiver 210, and is polarized to a first polarized direction. The second portion of the first reflected light beam LA transmits through the second polarizer 212 to the second receiver 216, and is polarized to a second polarized direction different from the first polarized direction.

In some embodiments, the first polarizer 206 is one of a S-type polarizer and a P-type polarizer, and the second polarizer 212 is the other of the S-type polarizer and the P-type polarizer.

As a result, the radiation detector 200A can measure the first reflected light beam in two different polarization directions, S-type and P-type, at the same time, which provides more information regarding the sample 16.

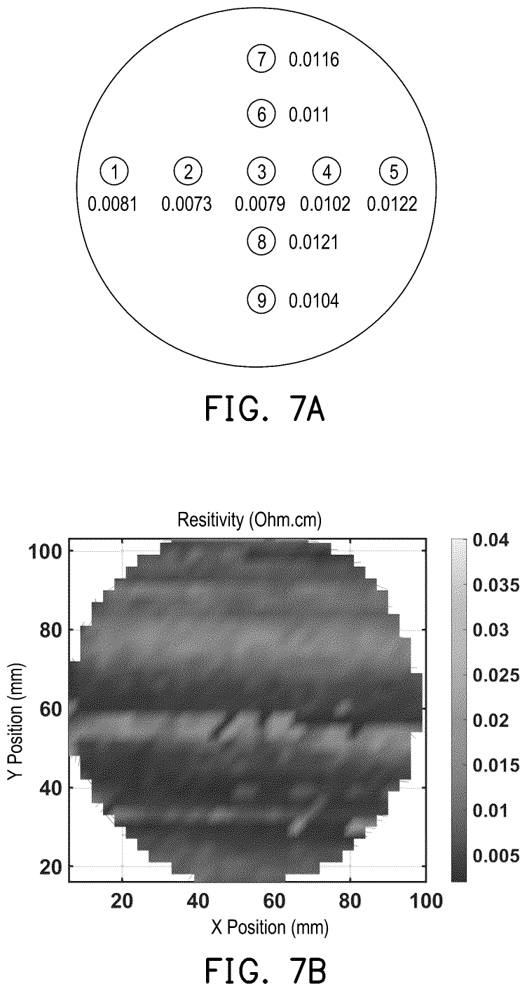

FIGS. 7A and 7B are examples of a measurement result of the measurement system according to an embodiment of the present disclosure.

One of the characteristic parameters of the wafer which the measurement system (as shown in previous embodiments) is able to measure is the resistivity of the wafer. As shown previously, the sample 16 is disposed on the sample stage 18, which is moveable along the X and Y direction, and is also rotatable. Thus, it is possible to measure the resistivity of the wafer on specific locations, or to scan the resistivity distribution of the wafer.

FIG. 7A is a measurement of the resistivity of the wafer on several different locations of the wafer. The measured result is compatible with results measured with other methods, such as Eddy current method.

FIG. 7B is a measurement of the resistivity distribution of the wafer on several different locations of the wafer. The measured result is compatible with results measured with other methods, such as Eddy current method.

In summary, a non-destructive measurement system based on THz radiation is provided. The off-axis arrangement of the light path of the THz radiation is able to compensate the optical axis mismatch of the THz radiation. The additional visible light provides another method to compensate the optical axis mismatch of the THz radiation. The THz radiation reflected by the sample is measured by the radiation detector, which is able to measure the reflected THz radiation in two different polarization directions simultaneously.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A radiation emitter, comprising:
a first light source, emitting a first light beam transmitting along a first light path;
a polarizer, disposed on the first light path of the first light beam; and
at least one mirror, disposed on the first light path of the first light beam, wherein the first light beam is reflected by a first mirror of the at least one mirror to leave the radiation emitter.

2. The radiation emitter according to claim 1, wherein the first light source is a photoconductive antenna.

3. The radiation emitter according to claim 1, wherein the first light beam is a THz radiation.

4. The radiation emitter according to claim 1, wherein the polarizer is a linear polarizer.

5. The radiation emitter according to claim 1, wherein the first mirror of the at least one mirror is an off-axis parabolic mirror.

6. The radiation emitter according to claim 1, wherein the radiation emitter further comprises:
a second light source, emitting a second light beam transmitting along a second light path,
wherein the second light beam is a visible light,
wherein after the second light beam being reflected by or transmitting through the first mirror of the at least one mirror, the second light path overlaps with the first light path.

7. The radiation emitter according to claim 6, wherein a first light spot of the first light beam formed on a sample and a second light spot of the second light beam formed on the sample are overlapping.

8. A measurement system, comprising:
a laser source, emitting a laser beam;
a beam splitter, split the laser beam into a first portion of the laser beam and a second portion of the laser beam;
a sample stage, configured to hold a sample;
a radiation emitter, receiving a first portion of the laser beam, comprising:
a first light source, emitting a first light beam, according to the first portion of the laser beam, transmitting along a first light path to the sample to generate a first reflected light beam;
a polarizer, disposed on the first light path of the first light beam; and
at least one mirror, disposed on the first light path of the first light beam, wherein the first light beam is reflected by a first mirror of the at least one mirror to leave the radiation emitter to the sample;
a radiation detector, receiving a second portion of the laser beam, comprising:
at least one receiver, receiving a portion of a first reflected light beam; and
a lock-in amplifier, connecting to the radiation detector and receiving detected signals from the radiation detector.

9. The measurement system according to claim 8, wherein the first light source is a photoconductive antenna.

10. The measurement system according to claim 8, wherein the first light beam is a THz radiation.

11. The measurement system according to claim 8, wherein the polarizer is a linear polarizer.

12. The measurement system according to claim 8, wherein the first mirror of the at least one mirror is an off-axis parabolic mirror.

13. The measurement system according to claim 8, wherein the radiation emitter further comprises:
a second light source, emitting a second light beam transmitting along a second light path to the sample to generate a second reflected light beam,
wherein the second light beam is a visible light,
wherein after the second light beam being reflected by or transmitting through the first mirror of the at least one mirror, the second light path overlaps with the first light path, and the second light beam is directed to the sample.

14. The measurement system according to claim 13, wherein a first light spot of the first light beam formed on the sample and a second light spot of the second light beam formed on the sample are overlapping.

15. The measurement system according to claim 8,
wherein the at least one receiver includes a first receiver and a second receiver,
wherein the radiation detector further includes:
a beam splitter, disposed on a third light path of the first reflected light beam, which splits the first reflected light beam to a first portion of the first reflected light beam and a second portion of the first reflected light beam;
a first polarizer, disposed between the beam splitter and the first receiver;
a second polarizer, disposed between the beam splitter and the second receiver,
wherein the first portion of the first reflected light beam transmits through the first polarizer to the first receiver, and is polarized to a first polarized direction,
wherein the second portion of the first reflected light beam transmits through the second polarizer to the second receiver, and is polarized to a second polarized direction different from the first polarized direction.

16. The measurement system according to claim 15, wherein the first polarizer is one of a S-type polarizer and a P-type polarizer, and the second polarizer is the other of the S-type polarizer and the P-type polarizer.

17. The measurement system according to claim 8, wherein the sample stage is an XY table.
